(19) United States
(12) Patent Application Publication
(10) Pub. No.: US 2025/0087564 A1
(43) Pub. Date: Mar. 13, 2025

(54) SEMICONDUCTOR PACKAGE WITH LATERALLY CONFINED SUBSTRATE AND METHODS FOR FORMING THE SAME

(71) Applicant: Taiwan Semiconductor Manufacturing Company Limited, Hsinchu (TW)

(72) Inventors: Hsien-Wei Chen, Hsinchu City (TW); Meng-Liang Lin, Hsinchu (TW); Ying-Ju Chen, Tuku Township (TW); Shin-Puu Jeng, Po-Shan Village (TW)

(21) Appl. No.: 18/464,399

(22) Filed: Sep. 11, 2023

(51) Int. Cl. H01L 23/498; H01L 21/56; H01L 21/683; H01L 23/00; H01L 23/31; H01L 23/538; H01L 25/065; H01L 25/10

(52) U.S. Cl. CPC H01L 23/49822; H01L 21/565; H01L 21/6835; H01L 23/3135; H01L 23/5381; H01L 24/16; H01L 24/32; H01L 24/73; H01L 24/96; H01L 24/97; H01L 25/0655; H01L 25/105; H01L 2224/16235; H01L 2224/32225; H01L 2224/73204; H01L 2224/96; H01L 2224/97; H01L 2924/3511

(57) ABSTRACT

Semiconductor packages and methods of fabricating semiconductor packages include an interposer, at least one semiconductor integrated circuit (IC) die mounted on a first surface of the interposer, a package substrate bonded to a second surface of the interposer, and a molding portion contacting the second surface of the interposer and laterally surrounding the package substrate. The package substrate may be laterally-confined with respect to the interposer such that at least one horizontal dimension of the package substrate may be less than the corresponding horizontal dimension of the interposer. In various embodiments, reliability of the bonding connections between the interposer and the package substrate may be improved thereby providing increased yields and improved package performance.

### BACKGROUND

Semiconductor devices are used in a variety of electronic applications. Some example uses may include personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer, and individual dies on the wafer are singulated by sawing between the integrated circuits along a scribe line. The individual dies are typically packaged separately, for example, in multi-chip modules, or in other types of packaging.

As semiconductor packages have become more complex, ensuring mechanical integrity of the package, including the electrical interconnections between various components of the package, has become more difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-section view of an intermediate structure during a process of forming a semiconductor package including an interposer located over a first carrier substrate according to various embodiments of the present disclosure.

FIG. 2 is a vertical cross-section view of the intermediate structure showing a plurality of semiconductor integrated circuit (IC) dies mounted over the first side surface of the interposer according to various embodiments of the present disclosure.

FIG. 3 is a vertical cross-section view of the intermediate structure showing an underfill material portion located between the lower surfaces of the semiconductor IC dies and the first side surface of the interposer according to various embodiments of the present disclosure.

FIG. 4 is a vertical cross-section view of the intermediate structure showing a first molding portion laterally surrounding the underfill material portion and the semiconductor IC dies according to various embodiments of the present disclosure.

FIG. 5 is a vertical cross-section view of the intermediate structure showing a second release layer located over the upper surfaces of the plurality of semiconductor dies, the exposed upper surface of the underfill material portion and the exposed upper surface of the first molding portion, and a second carrier substrate over the second release layer according to various embodiments of the present disclosure.

FIG. 6 is a vertical cross-section view of the intermediate structure showing the exemplary intermediate structure inverted (i.e., flipped over) such that the interposer and the plurality of semiconductor IC dies are located over and are supported by the second carrier substrate according to various embodiments of the present disclosure.

FIG. 7A is a vertical cross-section view of the intermediate structure showing a package substrate located over the second side surface of the interposer according to various embodiments of the present disclosure.

FIG. 7B is a horizontal plan bottom up view of the intermediate structure of FIG. 7A showing the package substrate located over the second side surface of the interposer according to various embodiments of the present disclosure.

FIG. 8 is a vertical cross-section view of the intermediate structure showing a second molding portion contacting the second side surface of the interposer and laterally surrounding the package substrate according to various embodiments of the present disclosure.

FIG. 9 is a vertical cross-section view of a semiconductor package according to various embodiments of the present disclosure.

FIG. 10 is a vertical cross-section view of a semiconductor package including a plurality of solder balls located on the lower surface of the package substrate and a ring structure mounted to the upper surface of the first molding portion according to various embodiments of the present disclosure.

FIG. 11 is a vertical cross-section view of a semiconductor package mounted to a supporting substrate according to various embodiments of the present disclosure.

FIG. 12 is a vertical cross-section view of a semiconductor package including a plurality of solder balls located on the lower surface of the package substrate, a thermal interface material (TIM) over the plurality of semiconductor IC dies, and a lid structure mounted to the upper surface of the first molding portion according to another embodiment of the present disclosure.

FIG. 13 is a vertical cross-section view of an intermediate structure including a functional component mounted over the second side surface of an interposer according to various embodiments of the present disclosure.

FIG. 14 is a vertical cross-section view of the intermediate structure showing a plurality of package substrates located over the second side surface of the interposer and the functional component according to various embodiments of the present disclosure.

FIG. 15 is a vertical cross-section view of the intermediate structure showing a second molding portion contacting the second side surface of the interposer and laterally surrounding each of the package substrates according to various embodiments of the present disclosure.

FIG. 16 is a vertical cross-section view of a semiconductor package according to various embodiments of the present disclosure.

FIG. 17 is a vertical cross-section view of a semiconductor package including a plurality of solder balls located on the lower surface of the package substrate and a ring structure mounted to the upper surface of the first molding portion according to various embodiments of the present disclosure.

FIG. 18 is a flowchart illustrating a method of fabricating a semiconductor package according to various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and in particular to semiconductor packages and methods of fabricating semiconductor packages that include an interposer, at least one semiconductor integrated circuit (IC) die mounted on a first surface of the interposer, a package substrate bonded to a second surface of the interposer, and a molding portion contacting the second surface of the interposer and laterally surrounding the package substrate. In various embodiments, the package substrate of the semiconductor package may be laterally-confined with respect to the interposer, such that at least one horizontal dimension of the package substrate may be less than the corresponding horizontal dimension of the interposer.

Typically, in a semiconductor package a number of semiconductor integrated circuit (IC) dies (i.e., “chips”) may be mounted onto a common substrate, which may also be referred to as a “package substrate.” In some semiconductor packages, such as in a fan out wafer level package (FOWLP) and/or fan-out panel level package (FOPLP), a plurality of semiconductor IC dies may be mounted to an interposer, such as an organic interposer or a semiconductor (e.g., silicon) interposer, that may include interconnect structures extending therethrough. The resulting package structure, including the interposer and the semiconductor IC dies mounted thereon, may then be mounted onto a surface of a package substrate using solder connections.

Many semiconductor packages may include a large number of semiconductor IC dies integrated in the semiconductor package. For example, semiconductor package for high speed advanced high-performance computing (HPC) applications may include a large number of different types of semiconductor IC dies (e.g., processing dies, memory dies, chiplets, etc.) integrated into a single package. To accommodate the relatively large number of semiconductor IC dies in the semiconductor package, the interposer and the package substrate of the semiconductor package may need to have relatively larger areas. However, an interposer and a package substrate having a larger area may result in mechanical instability of the package substrate. For example, it may be difficult to maintain coplanarity tolerances when bonding the interposer and the semiconductor IC dies mounted thereon to the package substrate. Larger sized interposers and package substrates may also be prone to cracking defects as well as poor signal integrity (SI) and/or power integrity (PI) characteristics. Accordingly, larger sized semiconductor packages may result in greater risk of defective bonds, poor performance, and/or lower yields.

In order to improve the performance and yields of semiconductor packages, various embodiments disclosed herein include semiconductor packages and methods of fabricating semiconductor packages that include an interposer, at least one semiconductor integrated circuit (IC) die mounted on a first surface of the interposer, a package substrate bonded to a second surface of the interposer, and a molding portion contacting the second surface of the interposer and laterally surrounding the package substrate. In various embodiments, the package substrate may be laterally-confined with respect to the interposer, such that at least one horizontal dimension of the package substrate may be less than the corresponding horizontal dimension of the interposer.

In various embodiments, one or more laterally-confined package substrates may be mounted to the second surface of the interposer while the interposer and the semiconductor IC dies are supported on a carrier substrate. In some embodiments, by bonding the package substrate to a package structure including the interposer and the semiconductor IC dies while the package structure is supported on a carrier substrate may provide additional mechanical support and inhibit thermal-induced warping during the bonding process. This may help to improve the coplanarity characteristics of the bonding structures (e.g., solder balls) that bond the package substrate(s) to the interposer. A molding portion (e.g., an epoxy mold compound (EMC)) may then be formed over the second surface of the interposer and laterally surrounding each of the package substrates to provide enhanced structural integrity to the semiconductor package. Accordingly, the bonding connections between the interposer and the package substrate may have increased reliability thereby providing increased yields and improved package performance within a compact package size. Various embodiments may also enable the use of relatively thicker interposer and/or relatively thinner package substrates, including “coreless” package substrates, which may help to improve the signal integrity (PI) and/or the power integrity (PI) characteristics of the semiconductor package.

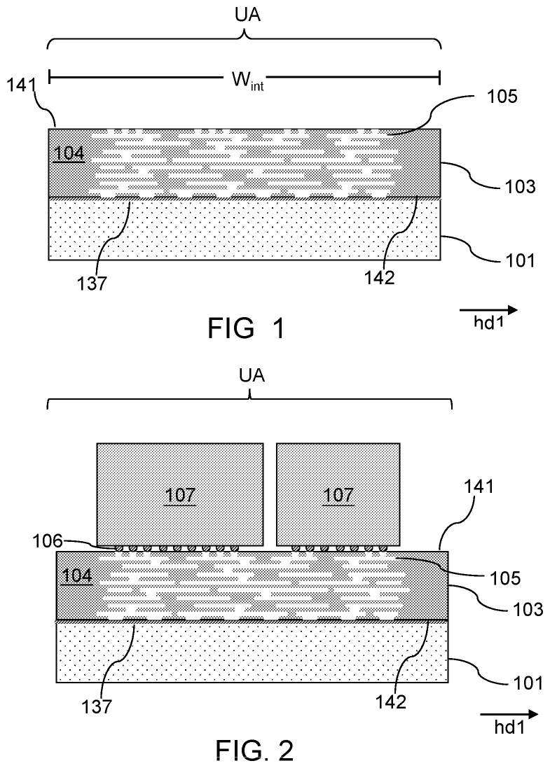

FIG. 1 is a vertical cross-section view of an intermediate structure during a process of forming a semiconductor package according to various embodiments of the present disclosure. Referring to FIG. 1, the intermediate structure includes a first carrier substrate 101 and an interposer 103 formed and mounted over a front side surface of the first carrier substrate 101. The first carrier substrate 101 may provide mechanical support to the interposer 103. The first carrier substrate 101 may be formed of a suitable substrate material, such as glass material, a ceramic material (e.g., a sapphire substrate), a semiconductor material (e.g., a silicon substrate), or the like. Other suitable materials for the first carrier substrate 101 are within the contemplated scope of disclosure. In some embodiments, the first carrier substrate 101 may be formed of an optically transparent material.

In some embodiments, a first release layer 137 may be located over the front side surface of the first carrier substrate 101, and the interposer 103 may be located over the first release layer 117. The first release layer 137 may include an adhesive material that may adhere the interposer 103 to the front side surface of the first carrier substrate 101. In some embodiments, the first release layer 137 may include an adhesive material that may be subsequently treated to cause the adhesive material of the first release layer 137 lose its adhesive properties, such that the first carrier substrate 101 may be separated from the interposer 103. In some embodiments, the adhesive material of the first release layer 137 may lose its adhesive properties when subjected to treatment using an energy source, such as a thermal, optical (e.g., UV, laser, etc.) and/or sonic (e.g., ultrasonic) energy source. In one non-limiting example, the first release layer 137 may include a light-to-heat conversion (LTHC) material that may selectively absorb optical radiation in certain wavelength range(s), such as ultraviolet radiation, causing the LTHC material to heat up and thereby lose adhesion. In other embodiments in which the first carrier substrate 101 is formed of an optically transparent material, the application of an optical energy source may cause the first release layer 137 to lose its adhesive property. Alternatively, the first release layer 137 may include an adhesive material, such as an acrylic pressure-sensitive adhesive material, that may decompose when subjected to an elevated temperature. Other suitable materials for the first release layer 137 are within the contemplated scope of disclosure.

Referring again to FIG. 1, the interposer 103 may include a first side surface 141 and a second side surface 142 opposite the first side surface. The second side surface 142 of the interposer 103 may face the front side surface of the first carrier substrate 101. A plurality of conductive interconnect structures 105 (e.g., metal lines and vias) may extend within the interposer 103 between the first side surface 141 and the second side surface of the interposer 103. The conductive interconnect structures 105 may be formed in and surrounded by an insulating matrix that may be composed of a dielectric material 104. The conductive interconnect structures 105 of the interposer 103 may be configured to route electrical signals between semiconductor integrated circuit (IC) dies and a package substrate in a semiconductor package to be subsequently formed. Thus, the conductive interconnect structures 105 of the interposer 103 may also be referred to as “redistribution structures.”

In some embodiments, the interposer 103 may be an organic interposer. The organic interposer 103 may be formed on the first carrier substrate 101. In one non-limiting example, the interposer 103 may be formed by sequentially depositing layers of a dielectric material 104, such as a dielectric polymer material, over the front side surface of the first carrier substrate 101 (and over the first release layer 117, in embodiments which include the first release layer 117). Each of the layers of dielectric material 104 may be lithographically patterned and etched to form open regions (e.g., trenches and/or via openings), and a metallization process may then be used to fill the open regions and form conductive interconnect structures 105 (e.g., metal lines and vias) within each successive layer of dielectric material 104. In this manner, the interposer 103 may be built layer-by-layer over the front side surface of the first carrier substrate 101. Each layer of a dielectric material 104 and corresponding conductive interconnect structures 105 of the interposer 103 may be referred to as a redistribution layer (RDL). In some embodiments, the interposer 103 may include at least two (2) redistribution layers (RDLs). In some embodiments, the interposer 103 may have a thickness between the first side surface 141 and the second side surface 142 of the interposer 103 that is at least 40 μm, such as between about 40 μm and about 80 μm. It will be understood that greater and lesser thicknesses for the interposer 103 may also be utilized.

In some embodiments, each of the layers of dielectric material 104 of the interposer 103 may include a suitable dielectric polymer material, such as polyimide (PI), benzocyclobutene (BCB), or polybenzobisoxazole (PBO). Other suitable dielectric materials are within the contemplated scope of disclosure. The layers of dielectric material 104 of the interposer 103 may be formed using a suitable deposition process, such as a spin coating and drying process. Other suitable deposition processes are within the contemplated scope of disclosure.

The conductive interconnect structures 105 of the interposer 103 may be formed of a suitable conductive material, such as Cu, Ni, W, Co, Mo, Ru, etc., including alloys and combinations of the same. In some embodiments, the conductive interconnect structures 105 may include a metallic barrier layer, such as a layer of Ti, TiN, TaN, or WN, contacting the dielectric material 104, and a metallic fill material, which may include an elemental metal (e.g., Cu, Ni, etc.) or an alloy or a combination thereof. Other suitable materials for the conductive interconnect structures 105 of the interposer 103 are within the contemplated scope of disclosure. The conductive interconnect structures 105 of the interposer 103 may be formed using any suitable deposition process. For example, suitable deposition processes may include physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof.

Referring again to FIG. 1, an instance of an interposer 103 located over the front side surface of the first carrier substrate 101 may be referred to as a unit area (UA) of the first carrier substrate 101. The interposer 103 may have an interposer width Wᵢₙₜ. A single unit area (UA) is illustrated in FIG. 1, although it will be understood that the first carrier substrate 101 may include a plurality of unit areas (UAs), where each unit area (UA) may include a separate instance of an interposer 103 over the front side surface of the first carrier substrate 101. For example, the first carrier substrate 101 may include a periodic two-dimensional array (such as a rectangular array) of unit areas (UAs), where each unit area (UA) of the array may include a separate instance of an interposer 103 over the front side surface of the carrier substrate 101. In some embodiments, each interposer 103 within a unit area (UA) of the array may have an identical structure. The plurality of interposers 103 over the first carrier substrate 101 may be continuous with one another, such that a continuous layer of dielectric material 104 may extend over the front side surface of the first carrier substrate 101, with separate instances of conductive interconnect structures 105 formed within the continuous layer of dielectric material 104 in each unit area (UA).

FIG. 2 is a vertical cross-section view of the intermediate structure showing a plurality of semiconductor integrated circuit (IC) dies 107 mounted over the first side surface 141 of the interposer 103 according to various embodiments of the present disclosure. Referring FIG. 2, in some embodiments, the plurality of semiconductor IC dies 107 may include at least one processor die, such as a system-on-chip (SoC), an application specific integrated circuit (ASIC) die, a central processing unit die, and/or a graphic processing unit die. In some embodiments, the plurality of semiconductor IC dies 107 may include at least one chiplet configured to perform specific, limited processing functions. In some embodiments, the plurality of semiconductor IC dies 107 may include at least one memory die, such as a high bandwidth memory (HBM) die and/or a dynamic random access memory (DRAM) die. In some embodiments, the plurality of semiconductor IC dies 107 may be homogeneous, meaning that all of the semiconductor IC dies 107 may be of the same type (e.g., all SoC dies, all HBM dies, all DRAM dies, etc.). Alternatively, the plurality of semiconductor IC dies 107 may be heterogeneous, meaning that the plurality of semiconductor IC dies 107 may include different types of semiconductor IC dies 107 (e.g., at least one processor die and at least one memory die). Although the embodiment of FIG. 2 illustrates two semiconductor IC dies 107 mounted to the interposer 103, it will be understood that a greater or lesser number of semiconductor IC dies 107 may be mounted to the interposer 103 in various embodiments.

Referring again to FIG. 2, a plurality of bonding structures 106 may bond each of the semiconductor IC dies 107 to the first side surface 141 of the interposer 103. In various embodiments, the semiconductor IC dies 107 may be mounted over the first side surface 141 of the interposer 103 by placing each of the semiconductor IC dies 107 over the first side surface 141 of the interposer 103 (e.g., using a pick-and-place apparatus). The semiconductor IC dies 107 may be aligned over the first side surface 141 of the interposer 103 such that semiconductor die bonding structures (e.g., metallic bumps, pillars, stacks and/or pads) on the lower surfaces of the semiconductor IC dies 107 contact corresponding interposer bonding structures (e.g., metallic bumps, pillars, stacks and/or pads) over the first side surface 141 of the interposer 103. A reflow process may be used to bond the semiconductor die bonding structures on the lower surfaces of the semiconductor IC dies 107 to the corresponding interposer bonding structures over the first side surface 141 of the interposer 103, thereby providing a mechanical and electrical connection between each of the semiconductor IC dies 107 and the interposer 103. In some embodiments, the semiconductor IC dies 107 may be bonded to the first side surface 141 of the interposer using microbump bonding (i.e., C2 bonding), although it will be understood that other bonding technologies and processes are within the contemplated scope of disclosure. In various embodiments, a plurality of semiconductor IC dies 107 may be mounted over the first side surface 141 of the interposer 103 within each unit area (UA) of the first carrier substrate 101.

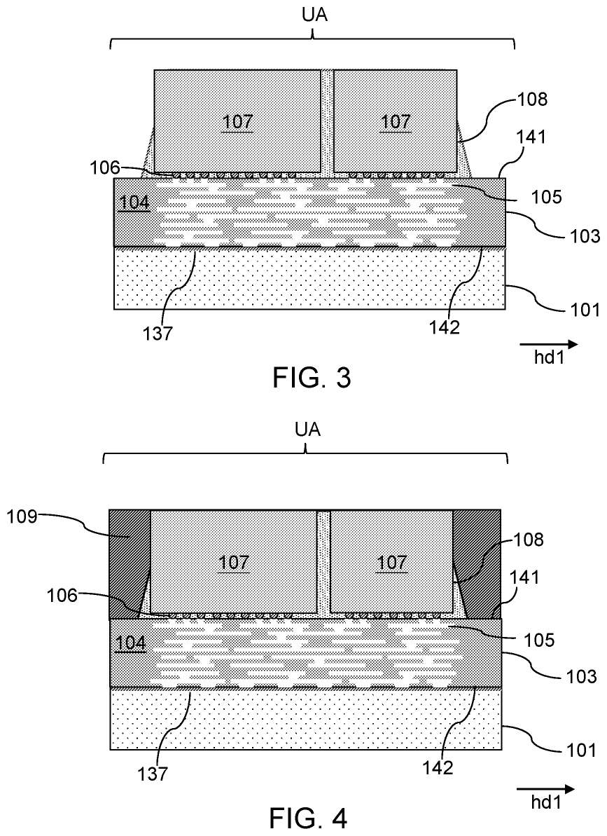

FIG. 3 is a vertical cross-section view of the intermediate structure showing an underfill material portion 108 located between the lower surfaces of the semiconductor IC dies 107 and the first side surface 141 of the interposer 103 according to various embodiments of the present disclosure. Referring to FIG. 3, the underfill material portion 108 may be applied into the spaces between the first side surface 141 of the interposer 103 and the plurality of semiconductor IC dies 107 mounted to the interposer 103. The underfill material portion 108 may laterally surround and contact each of the bonding structures 106 that bond the respective semiconductor IC dies 107 to the interposer 103. The underfill material portion 108 may also be located between adjacent semiconductor IC dies 107 of the plurality of semiconductor IC dies 107 mounted to the interposer 103.

The underfill material portion 108 may include any underfill material known in the art. For example, the underfill material portion 108 may be composed of an epoxy-based material, which may include a composite of resin and filler materials. Other suitable materials for the underfill material portion 108 are within the contemplated scope of disclosure. Any known underfill material application method may be used to apply the underfill material portion 108.

FIG. 4 is a vertical cross-section view of the intermediate structure showing a first molding portion 109 laterally surrounding the underfill material portion 108 and the semiconductor IC dies 107 according to various embodiments of the present disclosure. Referring to FIG. 4, a first molding portion 109 may laterally surround the plurality of semiconductor IC dies 107 mounted to the interposer 103. The first molding portion 109 may contact lateral side surfaces of at least some of the semiconductor IC dies 107 and may also contact the underfill material portion 108. In various embodiments, the first molding portion 109 may include an epoxy material. For example, the first molding portion 109 may include an epoxy mold compound (EMC) that may include epoxy resin, a hardener (i.e., a curing agent), silica or other filler material(s), and optionally additional additives. The EMC may be applied around the periphery of the semiconductor IC dies 107 in liquid or solid form, and may be hardened (i.e., cured) to form a first molding portion 109 having sufficient stiffness and mechanical strength surrounding the plurality of semiconductor IC dies 107. Portions of the first molding portion 109 that extend above a horizontal plane including the top surfaces of the semiconductor IC dies 107 may be removed using a planarization process, such as a chemical mechanical planarization (CMP) process.

In various embodiments, each unit area (UA) of the first carrier substrate 101 may include an underfill material portion 108 located between the first side surface 141 of the interposer 103 and the undersides of the plurality of semiconductor IC dies 107 mounted to the interposer 103, and a first molding portion 109 around the outer periphery of the plurality of semiconductor IC dies 107. In some embodiments, the first molding portion 109 may form a continuous matrix extending between the unit areas (UAs) of the first carrier substrate 101 and laterally surrounding and embedding the respective sets of semiconductor IC dies 107 within each of the unit areas (UAs) of the first carrier substrate 101.

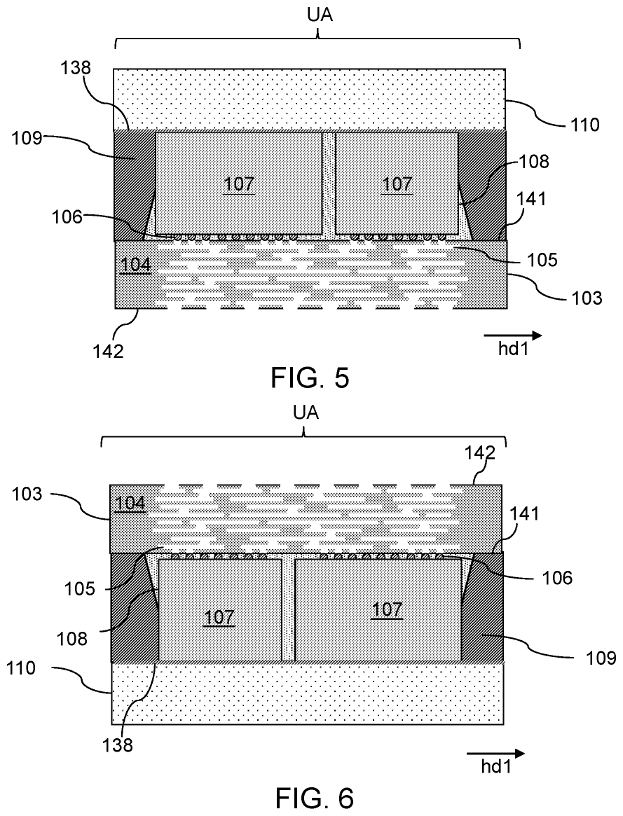

FIG. 5 is a vertical cross-section view of the intermediate structure showing a second release layer 138 located over the upper surfaces of the plurality of semiconductor dies 107, the exposed upper surface of the underfill material portion 108 and the exposed upper surface of the first molding portion 109, and a second carrier substrate 110 over the second release layer 138 according to various embodiments of the present disclosure. Referring to FIG. 5, the second release layer 138 may include an adhesive material that may adhere the second carrier substrate 110 to the upper surfaces of the plurality of semiconductor dies 107, the underfill material portion 108 and the first molding portion 109. As with the first release layer 137 described above, the second release layer 138 may also be configured to lose its adhesive properties when subjected to a treatment using an energy source, such as a thermal, optical (e.g., UV, laser, etc.) and/or sonic (e.g., ultrasonic) energy source. In some embodiments, the first release layer 137 and the second release layer 138 may be composed of the same material(s). Alternatively, the first release layer 137 and the second release layer 138 may be composed of different material(s).

Referring again to FIG. 5, the second carrier substrate 110 may be formed of a suitable substrate material, such as the materials described above with reference to the first carrier substrate 101 shown in FIG. 1. In some embodiments, the second carrier substrate 110 may be composed of the same material(s) as the first carrier substrate 101. Alternatively, the second carrier substrate 110 and the first carrier substrate 101 may be composed of different material(s). In various embodiments, the second carrier substrate 110 may extend over each of the unit areas (UAs) of the first carrier substrate 101 such that each unit area (UA) of the first carrier substrate 101 may correspond to an equivalent unit area (UA) of the second carrier substrate 110.

FIG. 5 additionally shows the first carrier substrate 101 removed from the intermediate structure. The first carrier substrate 101 may be removed using any suitable method known in the art. In embodiments in which the first carrier substrate 101 is adhered to the interposer 103 by a first release layer 137, the first release layer 137 may be subjected to a treatment that causes the first release layer 137 to lose its adhesive properties. This may enable the first carrier substrate 101 to be separated from the exemplary intermediate structure. For example, the first release layer 137 may include a light-to-heat conversion (LTHC) material that may be irradiated by optical radiation in a specified wavelength range, such as ultraviolet radiation, causing the LTHC material to heat up and thereby lose adhesion. The first release layer 137 may optionally be irradiated through the first carrier substrate 101 in embodiments in which the first carrier substrate 101 is composed of an optically-transparent material. Alternatively, the first release layer 137 may include a thermally-decomposing adhesive material. The exemplary intermediate structure be subjected to a thermal anneal process at a debonding temperature sufficient to cause the first release layer 137 to decompose and thereby enable the first carrier substrate 101 to be detached from the exemplary intermediate structure. In embodiments in which a thermal anneal process is used to remove the first carrier substrate 101, the debonding temperature used to thermally decompose the first release layer 137 may not be sufficient cause the second release layer 138 to lose its adhesive properties.

FIG. 6 is a vertical cross-section view of the intermediate structure showing the exemplary intermediate structure inverted (i.e., flipped over) such that the interposer 103 and the plurality of semiconductor IC dies 107 are located over and are supported by the second carrier substrate 110. The intermediate structure may be inverted either prior to or following the removal of the first carrier substrate 101.

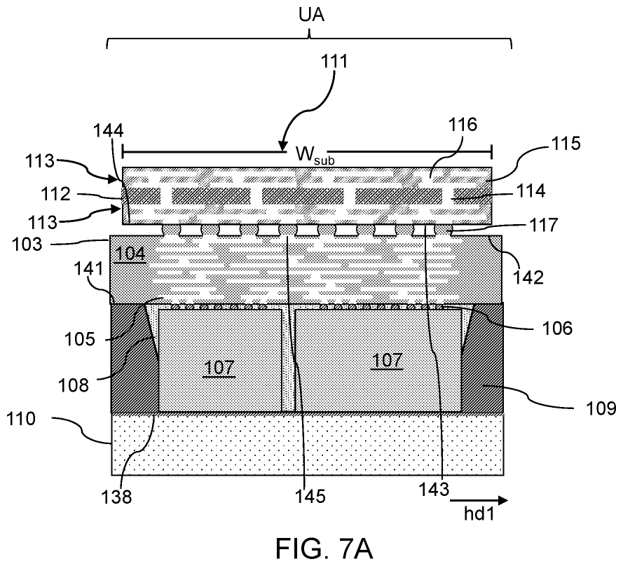

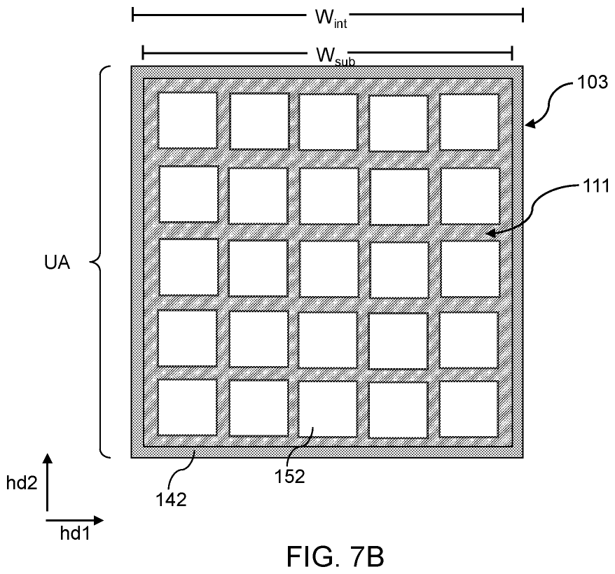

FIG. 7A is a vertical cross-section view of the intermediate structure showing a package substrate 111 located over the second side surface 142 of the interposer 103 according to various embodiments of the present disclosure. FIG. 7B is a horizontal plan bottom up view of the intermediate structure of FIG. 7A showing the package substrate 111 located over the second side surface 142 of the interposer 103. In various embodiments, the package substrate 111 may include a dielectric material matrix 115 with conductive interconnect features 114, 116 (e.g., metal lines, vias, bonding pads, etc.) located in and extending through the dielectric material matrix 115. In some embodiments, the package substrate 111 may include a solid substrate core 112 with conductive interconnect features 114 (e.g., vias) extending through the substrate core 112. In one exemplary embodiment, the substrate core 112 may be composed of a sheet of laminate reinforced resin. Redistribution structures 113 may be formed over the front and rear surfaces of the substrate core 113. The redistribution structures 113 may include layers of a polymer-based dielectric material, such as Ajinomoto Buildup Film (ABF)® product from Ajinomoto Co., Inc., Tokyo, JP, having conductive interconnect features 116 (e.g., metal lines, vias and/or bonding pads) formed on and/or within the layers of dielectric material. An optional outer coating layer (e.g., a solder resist layer) may be located over the redistribution structures 113. Other suitable materials and/or configurations for the package substrate 111 are within the contemplated scope of disclosure. In some embodiments, the package substrate 111 may be a “coreless” package substrate 111 that does not include a substrate core 113, as described in further detail below. In some embodiments, the package substrate 111 may have a thickness that is ˜1.8 mm or less, such as between about 0.2 mm and about 1.8 mm. It will be understood that greater and lesser thicknesses for the package substrate 111 may also be utilized.

Referring again to FIGS. 7A and 7B, the package substrate 111 may be bonded to the second side surface 142 of the interposer 103 via a plurality of bonding material portions 117 (e.g., solder connections). To bond the package substrate 111 to the interposer 103, the package substrate 111 may be aligned over the second side surface 142 of the interposer 103 such that a first side surface 143 of the package substrate 111 faces the second side surface 142 of the interposer 103. A plurality of bonding material portions 117 (e.g., solder balls) may be located between bonding pads 144 on the first side surface 143 of the package substrate 111 and corresponding bonding pads 145 on the second side surface 142 of the interposer 103. A reflow process may be performed to reflow the bonding material portions 117, thereby inducing bonding between the package substrate 111 and the interposer 103. The reflow process may be performed at an elevated temperature, such as between 150° C. and 350° C. (e.g., ˜ 250° C.). Following the reflow process, each of the bonding material portions 117 may be bonded to a respective one of the bonding pads 144 on the first side surface 143 of the package substrate 111 and to a respective one of the bonding pads 145 on the second side surface 142 of the interposer 103. In some embodiments, the bonding material portions 117 may include C4 solder balls, and the package substrate 111 may be bonded to the interposer 103 through an array of C4 solder balls.

In various embodiments, a package substrate 111 as shown in FIGS. 7A and 7B may be mounted over the interposer 103 within each of the unit areas (UAs) of the second carrier substrate 110. Each of the package substrates 111 may be laterally confined with respect to the underlying interposer 103 in each of the unit areas (UAs).

In particular, each of the package substrates 111 may have a dimension along at least one horizontal direction (e.g. hd1 and or hd2 in FIGS. 7A and 7B) that is less than the corresponding dimension of the interposer 103 to which the package substrate 111 is bonded. Put another way, the package substrate width, Wsub, may be less than the interposer width, Wᵢₙₜ along one or both horizontal directions hd1 and hd2 In some embodiments, the dimensions of the package substrate 111 along two perpendicular horizontal directions may be less than the corresponding dimensions of the interposer 103 to which the package substrate 111 is bonded (i.e., the package substrate width along two perpendicular horizontal directions may be less than the interposer width, Wᵢₙₜ along the two perpendicular horizontal directions). In some embodiments, the horizontal cross-section area of each package substrate 111 may be less than the horizontal cross-section area of the interposer 103 to which the package substrate 111 is bonded. This may be in contrast with related semiconductor packages in which the package substrate may have a larger area than the interposer. As shown in the embodiment illustrated in FIG. 7B, the package substrate 111 may be less in the two horizontal directions hd1, hd2 than the interposer 103. Bonding pads 152 shown on the bottom of the package substrate 111 are shown in the array. In other embodiments, fewer or more bonding pads 152 may be provided.

The method of fabrication of a semiconductor package in accordance with various embodiments of the present disclosure may also be different than methods that are currently used to fabricate related semiconductor packages. For example, in related methods for manufacturing a package substrate, a dicing process may be used to separate each unit area (UA) of the intermediate structure to provide a plurality of discrete package structures, where each package structure includes an interposer 103, a plurality of semiconductor IC dies 107 mounted over a first side surface 142 of the interposer 103, an underfill material portion 108 between the semiconductor IC dies 107 and the first side surface 142 of the interposer 103, and a molding portion 109 laterally surrounding the plurality of semiconductor IC dies 107. Then, each of the package structures may be aligned over and bonded to a surface of a package substrate via a plurality of bonding material portions 117 (e.g., solder connections). The package substrate typically has a larger horizontal cross-section area than the horizontal cross-section area of the package structure. However, as discussed above, with increasing numbers of semiconductor IC dies 107 mounted on an interposer 103 and/or increasing size of the interposer 103, it becomes increasingly difficult to maintain coplanarity tolerances of the plurality of bonding material portions 117 (e.g., solder balls) when bonding the package structure to the package substrate 111. This may be due at least in part to thermal-induced warpage of the package structure during the process of bonding the package structure to the package substrate. Thus, the risk of defective bonds and other defects, such as crack formation, may increase, resulting in poor semiconductor package performance and/or reduced yields.

In various embodiments of the present disclosure, a laterally-confined package substrate 111 may be mounted to the second side surface 142 of the interposer 103 prior to singulation (e.g., dicing) of the individual unit areas (UA) of the exemplary intermediate structure—i.e., while the interposer 103 and the semiconductor IC dies 107 are supported on the second carrier substrate 110. This may help to improve the coplanarity characteristics of the bonding material portions 117 (e.g., solder balls) that form the bonding connections between the package substrate 111 and the second side surface 142 of the interposer 103. In some embodiments, a coplanarity tolerance may be defined as a maximum allowable height difference between the surfaces of the bonding material portions 117 and a reference plane (i.e., a seating plane). In various embodiments, the coplanarity of the bonding material portions 117 during the bonding of the laterally-confined package substrate 111 to the second side surface 142 of the interposer 103 as shown in FIG. 7 may be less than 12 mils (i.e., 304.8 μm). This may result in an increased reliability of the bonding connections between the interposer 103 and the package substrate 111 thereby providing increased yields and improved package performance within a compact package size.

In some embodiments, package performance and routing density management may also be improved by utilizing a relatively thicker interposer 103 (e.g., ≥40 μm) and a relatively thinner package substrate 111 (e.g., ≤1.8 mm). Accordingly, a relatively greater portion of the redistribution structures and/or redistribution layers may be provided in the interposer 103 rather than in the package substrate 111, which may help to improve signal integrity (SI) and/or power integrity (PI) characteristics of the semiconductor package.

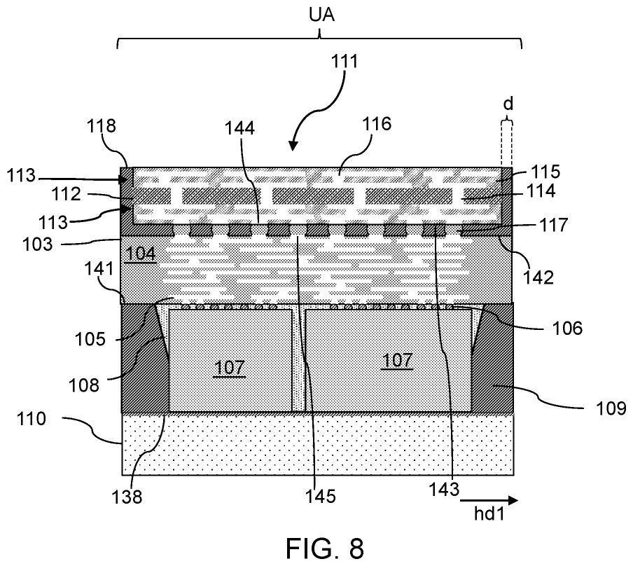

FIG. 8 is a vertical cross-section view of the exemplary intermediate structure showing a second molding portion 118 contacting the second side surface 142 of the interposer 103 and laterally surrounding the package substrate 111 according to various embodiments of the present disclosure. Referring to FIG. 8, the second molding portion 118 may contact the second side surface 142 of the interposer 103 and may extend at least partially within the gap between the second side surface 142 of the interpose 103 and the package substrate 111. In some embodiments, the second molding portion 118 may contact and may laterally surround some or all of the bonding material portions 117 that bond the package substrate 111 and the interposer 103. In some embodiments, an underfill material portion 108 such as described above with reference to FIG. 3 may not be present between the package substrate 111 and the interposer 103. The second molding portion 118 may also laterally surround the package substrate 111. In some embodiments, a thickness, d, of the second molding portion 118 over the side surfaces of the package substrate 111 within each unit area (UA) may be at least about 40 μm, such as between about 40 μm and about 2000 μm.

In various embodiments, the second molding portion 118 may include an epoxy material. For example, the second molding portion 118 may include an epoxy mold compound (EMC) that may include epoxy resin, a hardener (i.e., a curing agent), silica or other filler material(s), and optionally additional additives. The EMC may be applied over the second side surface 142 of the interposer 103 and around the periphery of the package substrate 111 in liquid or solid form, and may be hardened (i.e., cured) to form a second molding portion 118 having sufficient stiffness and mechanical strength surrounding the package substrate 111. Portions of the second molding portion 118 that extend above a horizontal plane including the upper surface of the package substrate 111 may be removed using a planarization process, such as a chemical mechanical planarization (CMP) process. Accordingly, an upper surface of the second molding portion 118 may be substantially coplanar with the upper surface of the package substrate 111. In some embodiments, the second molding portion 118 may include the same material(s) as the first molding portion 109 described above with reference to FIG. 4. Alternatively, the second molding portion 118 may be composed of different material(s) as the first molding portion 109.

In various embodiments, each unit area (UA) of the second carrier substrate 110 may include a second molding portion 118 laterally surrounding a package substrate 111. In some embodiments, the second molding portion 118 may form a continuous matrix extending between the unit areas (UAs) of the second carrier substrate 110 and laterally surrounding a package substrate 111 within each of the unit areas (UAs) of the second carrier substrate 110.

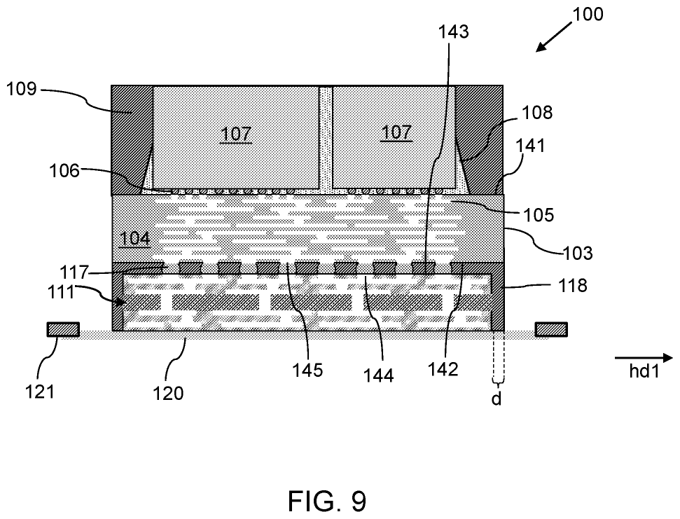

FIG. 9 is a vertical cross-section view of a semiconductor package 100 according to various embodiments of the present disclosure. Referring to FIG. 9, the second carrier substrate 110 may be removed from the exemplary intermediate structure shown in FIG. 8. The second carrier substrate 110 may be removed using any suitable method known in the art, such as any of the methods described above for removal of the first carrier substrate 101. In embodiments in which the second carrier substrate 110 is adhered to the semiconductor IC dies 107, the underfill material portion 108 and the first molding portion 109 using a second release layer 138, the second release layer 138 may be subjected to a treatment that causes the second release layer 138 to lose its adhesive properties, such as a thermal anneal and/or an optical irradiation treatment process as described above with reference to FIG. 5.

A dicing process may be used to separate each unit area (UA) of the exemplary intermediate structure to provide a plurality of discrete semiconductor packages 100. Each semiconductor package 100 may include an interposer 103, a plurality of semiconductor IC dies 107 mounted over a first side surface 141 of the interposer 103, an underfill material portion 108 located in the gaps between the first side surface 141 of the interposer 103 and each of the semiconductor IC dies 107, and a first molding portion 109 laterally surrounding the plurality of semiconductor IC dies 107. A second side surface 142 of the interposer 103 may be bonded to a package substrate 111 by a plurality of bonding material portions 117. The package substrate 111 may be laterally confined with respect to the interposer 103 such that at least one horizontal dimension of the interposer 103 may be greater than the corresponding horizontal dimension of the package substrate 111. A second molding portion 118 may contact the second side surface 142 of the interposer 103 and may laterally surround the package substrate 111. In some embodiments, a thickness, d, of the second molding portion 118 over the side surfaces of the package substrate 111 may be at least about 40 μm, such as between about 40 μm and about 2000 μm. The side surfaces of the semiconductor package 100 may be formed by the first molding portion 109, the interposer 103, and the second molding portion 118.

Referring again to FIG. 9, the semiconductor package 100 may be disposed on a suitable support element, which may be a flexible support, such as a dicing tape 120 supported by a tape frame 121. The semiconductor package 100 may be inverted (i.e., flipped over) relative to the orientation shown in FIG. 8 such that the interposer 103 and the plurality of semiconductor IC dies 107 may be located over the package substrate 111.

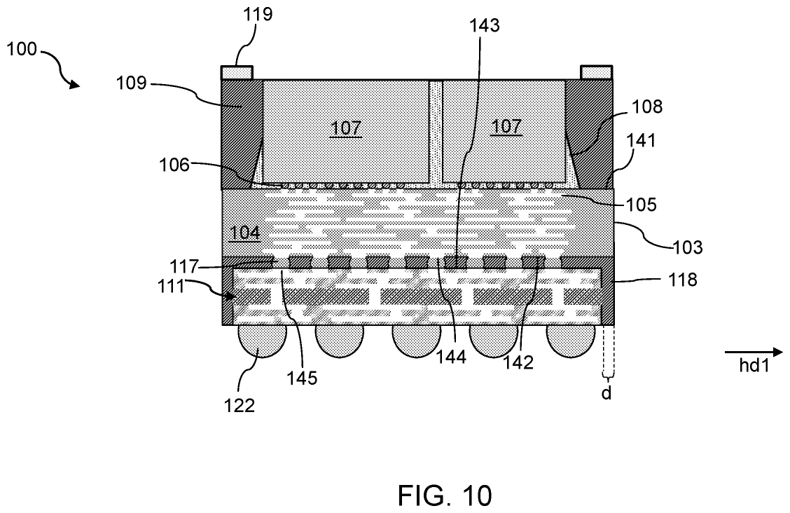

FIG. 10 is a vertical cross-section view of a semiconductor package 100 including a plurality of solder balls 122 located on the lower surface of the package substrate 111 and a ring structure 119 mounted to the upper surface of the first molding portion 109 according to various embodiments of the present disclosure. Each of the solder balls 122 may contact bonding pads exposed through the lower surface of the package substrate 111. The solder balls 122 may be used to mount the semiconductor package 100 onto a support substrate containing electrical interconnects, such as a printed circuit board (PCB). In some embodiments, the solder balls 122 may include a ball grid array (BGA), and the semiconductor package 100 may be mounted to the support substrate via a BGA connection.

Referring again to FIG. 10, a ring structure 119 may be mounted to the upper surface of the first molding portion 109. The ring structure 119 may include a suitable structural material, such as copper or stainless steel. The ring structure 119 may provide additional mechanical strength to the semiconductor package 100 and may help to inhibit warpage.

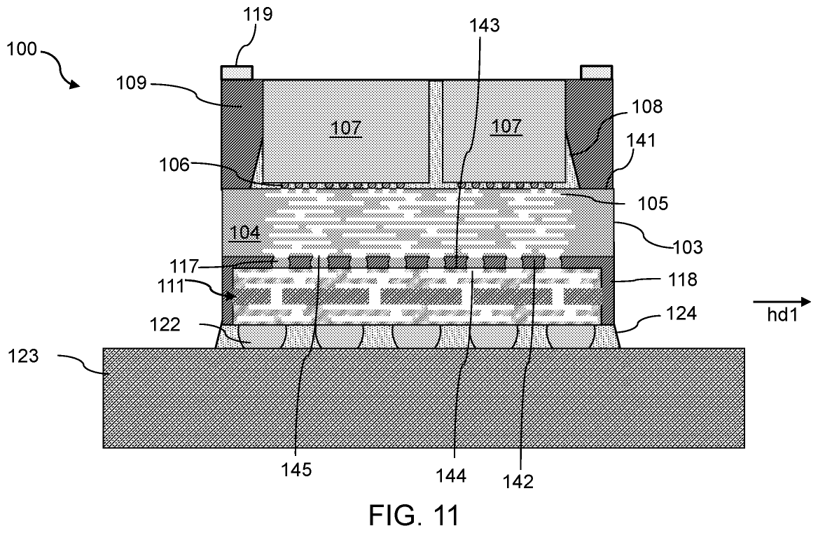

FIG. 11 is a vertical cross-section view of a semiconductor package 100 mounted to a supporting substrate 123 according to various embodiments of the present disclosure. Referring to FIG. 11, the supporting substrate 123 may be a printed circuit board (PCB) including an array of bonding pads on an upper surface of the supporting substrate 123. The pattern of the bonding pads on the upper surface of the supporting substrate 123 may correspond to the pattern of bonding pads on the lower surface of the package substrate 111. The semiconductor package 100 may be aligned over the upper surface of the support substrate 123 and a reflow process may be performed to reflow the solder balls 122, thereby inducing bonding between the package substrate 111 of the semiconductor package 100 and the supporting substrate 123. Each of the solder balls 122 may be bonded to a respective one of the bonding pads on the lower surface of the package substrate 111 and a respective one of the bonding pads on the upper surface of the supporting substrate 123. An optional underfill material portion 124 may be applied into the space between the lower surface of the package substrate 111 and the upper surface of the supporting substrate 123. The underfill material portion 124 may laterally surround and contact each of the solder balls 122 that bond the package substrate 111 to the supporting substrate 123.

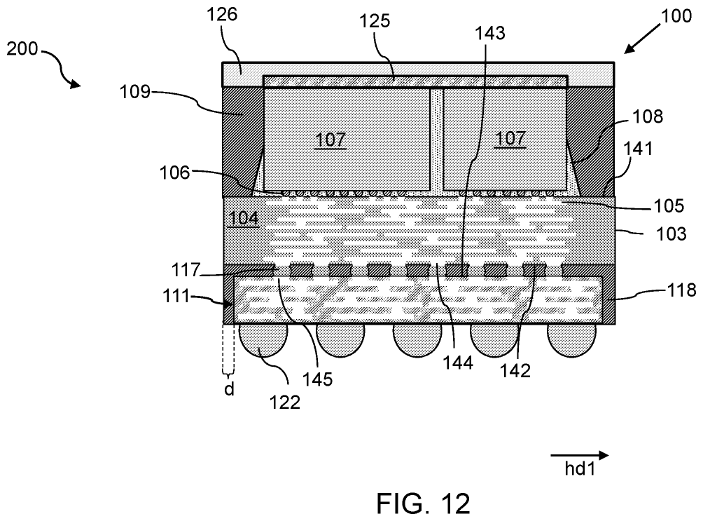

FIG. 12 is a vertical cross-section view of a semiconductor package 100 including a plurality of solder balls 122 located on the lower surface of the package substrate 111, a thermal interface material (TIM) 125 over the plurality of semiconductor IC dies 107, and a lid structure 126 mounted to the upper surface of the first molding portion 109 according to another embodiment of the present disclosure. The semiconductor package 100 shown in FIG. 12 may be similar to the semiconductor package 100 described above with reference to FIG. 10. Thus, repeated description of like features is omitted for brevity. The semiconductor package 100 shown in FIG. 12 differs from the semiconductor package 100 of FIG. 10 in that a thermal interface material (TIM) 125 is located over the plurality of semiconductor IC dies 107 and a lid structure 126 is mounted to the upper surface of the first molding portion 109. The TIM 125 may include a suitable material to promote heat transfer from the semiconductor IC dies 107. Suitable materials for the TIM 125 may include, for example, aluminum gel, graphite, indium metal, and the like. The lid structure 126 may include a suitable structural material, such as copper or stainless steel. The lid structure 126 may extend over and may be in thermal contact with the TIM 125. The lid structure 126 may be in lieu of, or may be in addition to, a ring structure 119 as described above with reference to FIG. 10. For example, in various embodiments, a ring structure may be omitted 199 and the lid structure 126 may be mounted directly to the upper surface of the first molding portion 109. Alternatively, a ring structure 119 may be mounted to the upper surface of the first molding portion 109 and a lid structure 126 may be mounted to the ring structure 119. In still further embodiments, both a ring structure 119 and a lid structure 126 may be mounted to different regions of the first molding portion 109. The TIM 125 and the lid structure 126 may provide improved thermal management for the semiconductor package 100. The lid structure 126 may also provide protection for the semiconductor package 100 and may enhance the structural integrity of the semiconductor package 100. The semiconductor package 100 as shown in FIG. 12 may be mounted onto a support substrate (e.g., a PCB) as shown in FIG. 11.

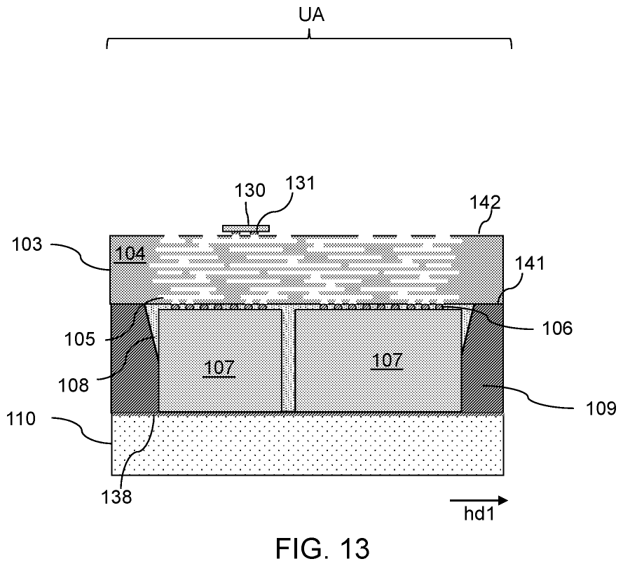

FIGS. 13-17 are sequential vertical cross-section views illustrating a process of fabricating a semiconductor package 100 according to another embodiment of the present disclosure. FIG. 13 is a vertical cross-section view of an intermediate structure including a functional component 130 mounted over the second side surface 142 of an interposer 103 according to various embodiments of the present disclosure. The intermediate structure of FIG. 13 may be derived from the intermediate structure described above with reference to FIG. 6. Thus, repeated discussion of like features is omitted for brevity. In the intermediate structure of FIG. 13, one or more functional components 130 may be mounted over the second side surface 142 of the interposer 103. The one or more functional components 130 may include a semiconductor material (e.g., silicon). The one or more functional components 130 may include, without limitation, a chiplet, an intelligent power device (IPD), and/or a bridge die, such as a local-silicon interconnect (LSI), that may be used to bridge two or more semiconductor IC dies 107 mounted to the first side surface 141 of the interposer 103. Other suitable functional components 130 are within the contemplated scope of disclosure. Bonding structures 131, such as microbump bonding structures, may be used to bond the one or more functional components 130 to the second side surface 142 of the interposer 103.

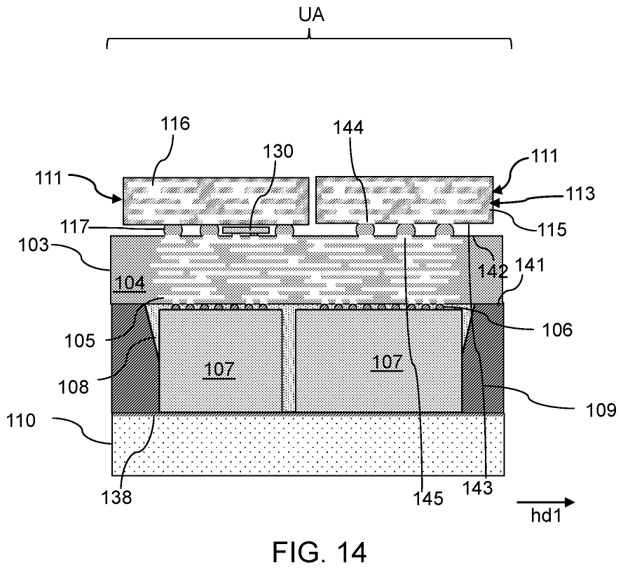

FIG. 14 is a vertical cross-section view of the exemplary intermediate structure showing a plurality of package substrates 111 located over the second side surface 142 of the interposer 103 and the functional component 130 according to various embodiments of the present disclosure. Referring to FIG. 14, each of the package substrates 111 may include a dielectric material matrix 115 with conductive interconnect features 116 (e.g., metal lines, vias, bonding pads, etc.) located in and extending through the dielectric material matrix 115. In the embodiment shown in FIG. 14, a pair of package substrates 111 are illustrated over the second side surface 142 of the interposer 103 within the unit area (UA), although it will be understood that more than two package substrates 111 may be located over the second side surface 142 of the interposer 103 within the unit area (UA).

In the embodiment of FIG. 14, the package substrates 111 are “coreless” package substrates 111 that lack a solid substrate core 112 as described above with reference to FIGS. 7A and 7B. Rather, the package substrates 111 may include a dielectric material 115 (e.g., a buildup film, an organic material layer, a polymer film, an oxide layer, a nitride layer or combinations thereof) with conductive interconnect features 116 formed within the dielectric material 115. In some embodiments, a coreless package substrate 111 may be fabricated by forming layers of redistribution structures 113 as described above with reference to FIGS. 7A and 7B over a carrier substrate, and separating the layers of redistribution structures 113 from the carrier substrate to provide a coreless package substrate 111. An optional outer coating layer (e.g., a solder resist layer) may be located over the redistribution structures 113. Other suitable materials and/or configurations for the package substrate 111 are within the contemplated scope of disclosure. In some embodiments, one or more of the plurality of package substrates 111 over the second side surface 142 of the interposer 103 may include a solid substrate core 112 as described above. In some embodiments, each of the package substrates 111 may have a thickness that is ˜1.8 mm or less, such as between about 0.2 mm and about 1.8 mm. It will be understood that greater and lesser thicknesses for the package substrates 111 may also be utilized.

Referring again to FIG. 14, each of the package substrates 111 may be bonded to the second side surface 142 of the interposer 103 via a plurality of bonding material portions 117 (e.g., solder connections). To bond the package substrates 111 to the interposer 103, the package substrate 111 may be aligned over the second side surface 142 of the interposer 103 such that a first side surface 143 of the package substrate 111 faces the second side surface 142 of the interposer 103. One or more of the package substrates 111 may at least partially overlie a functional component 130, as shown in FIG. 14. A plurality of bonding material portions 117 (e.g., solder balls) may be located between bonding pads 144 on the first side surface 143 of each of the package substrates 111 and corresponding bonding pads 145 on the second side surface 142 of the interposer 103. A reflow process may be performed to reflow the bonding material portions 117, thereby inducing bonding between each of the package substrates 111 and the interposer 103. The reflow process may be performed at an elevated temperature, such as between 150° C. and 350° C. (e.g., ˜ 250° C.). Following the reflow process, each of the bonding material portions 117 may be bonded to a respective one of the bonding pads 144 on the first side surface 143 of a package substrate 111 and to a respective one of the bonding pads 145 on the second side surface 142 of the interposer 103. In some embodiments, the bonding material portions 117 may include C4 solder balls, and the package substrates 111 may be bonded to the interposer 103 through an array of C4 solder balls. In some embodiments, following the bonding process, the first side surfaces 143 of the package substrates 111 may be vertically spaced from the underlying functional component(s) 130. Alternatively, one or more of the package substrates 111 may contact an underlying functional component 130.

In various embodiments, multiple package substrates 111 as shown in FIG. 14 may be mounted over the second side surface 142 of the interposer 103 within each of the unit areas (UAs) of the second carrier substrate 110. The package substrates 111 may be laterally spaced from one another. As in the embodiment described above with reference to FIGS. 7A and 7B, each of the package substrates 111 may be laterally-confined with respect to the interposer 103 such that one or more horizontal dimensions of each package substrate 111 is less than the corresponding dimension(s) of the interposer 103. In some embodiments, the peripheral edges of the plurality of package substrates 111 within each unit area (UA) may be spaced from the peripheral edges of the interposer 103 within the unit area (UA), as shown in FIG. 14.

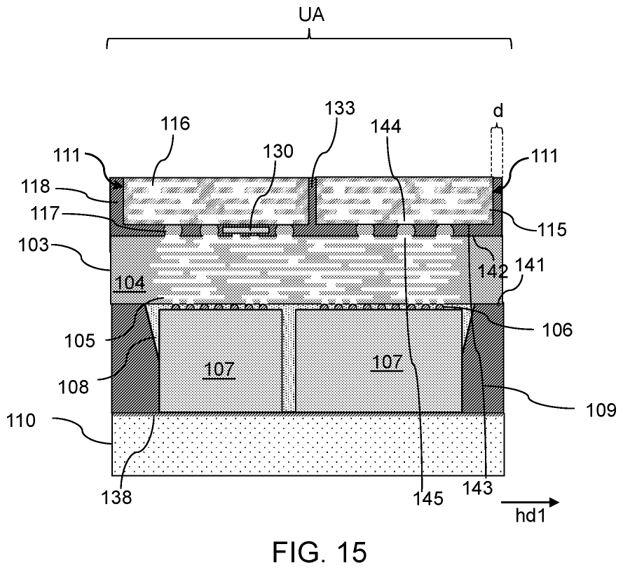

FIG. 15 is a vertical cross-section view of the exemplary intermediate structure showing a second molding portion 118 contacting the second side surface 142 of the interposer 103 and laterally surrounding each of the package substrates 111 according to various embodiments of the present disclosure. Referring to FIG. 15, the second molding portion 118 may contact the second side surface 142 of the interposer 103 and may extend at least partially within the gaps between the second side surface 142 of the interposer 103 and each of the package substrates 111. In some embodiments, the second molding portion 118 may contact and may laterally surround some or all of the bonding material portions 117 that bond the package substrates 111 and the interposer 103. In some embodiments, the second molding portion 118 may contact each of the functional components 130 mounted to the second side surface 142 of the interposer 103. In some embodiments, the second molding portion 118 may laterally surround each of the functional components 130 and may be located within the gap between the lower surface of each of the functional components 130 and the second side surface 142 of the interposer 103. The second molding portion 118 may also fill the gap(s) between the upper surface of each functional component 130 and the first side surface 143 of the package substrate(s) 111 that overlie the respective functional components 130.

The second molding portion 118 may laterally surround each of the package substrates 111 bonded to the second side surface 142 of the interposer 103. Thus, the second molding portion 118 may be located within and may fill the gaps 133 between adjacent package substrates 111 in each unit area (UA). The second molding portion 118 may also extend around the periphery of the plurality of package substrates 111 within each unit area (UA). A thickness, d, of the second molding portion 118 over the side surfaces of the package substrate 111 between the periphery of the package substrates 111 and the periphery of the unit area (UA) may be at least about 40 μm, such as between about 40 μm and about 2000 μm.

In various embodiments, the second molding portion 118 may be composed of a suitable material, such as an epoxy material, as described above with reference to FIG. 8. Portions of the second molding portion 118 that extend above a horizontal plane including the upper surfaces of the package substrates 111 may be removed using a planarization process, such as a chemical mechanical planarization (CMP) process. Accordingly, an upper surface of the second molding portion 118 may be substantially coplanar with the upper surfaces of the package substrates 111. In some embodiments, the second molding portion 118 may include the same material(s) as the first molding portion 109 described above with reference to FIG. 4. Alternatively, the second molding portion 118 may be composed of different material(s) as the first molding portion 109.

In various embodiments, each unit area (UA) of the second carrier substrate 110 may include a second molding portion 118 laterally surrounding a plurality of package substrates 111. In some embodiments, the second molding portion 118 may form a continuous matrix extending between the unit areas (UAs) of the second carrier substrate 110 and laterally surrounding a plurality of package substrates 111 within each of the unit areas (UAs) of the second carrier substrate 110.

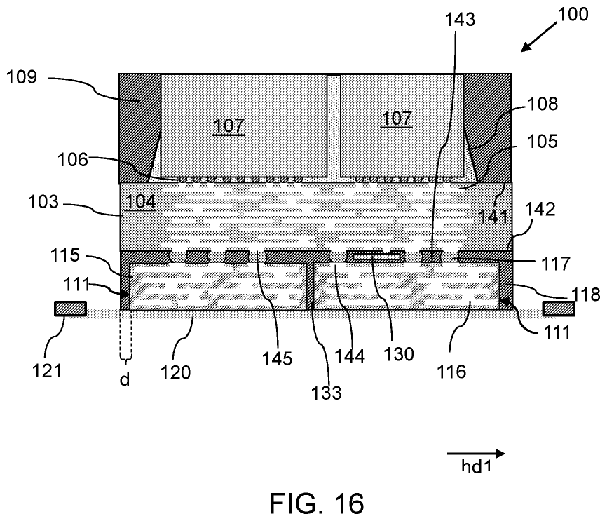

FIG. 16 is a vertical cross-section view of a semiconductor package 100 according to various embodiments of the present disclosure. Referring to FIG. 16, the second carrier substrate 110 may be removed from the exemplary intermediate structure as described above with reference to FIG. 9. A dicing process may be used to separate each unit area (UA) of the exemplary intermediate structure to provide a plurality of discrete semiconductor packages 100. Following the dicing process, the semiconductor package 100 may be disposed on a suitable support element, such as a dicing tape 120 supported by a tape frame 121. The semiconductor package 100 may be inverted (i.e., flipped over) relative to the orientation shown in FIG. 15 such that the interposer 103 and the plurality of semiconductor IC dies 107 may be located over the plurality of package substrates 111.

Referring again to FIG. 16, a semiconductor package 100 according to various embodiments may include an interposer 103, a plurality of semiconductor IC dies 107 mounted over a first side surface 141 of the interposer 103, an underfill material portion 108 located in the gaps between the first side surface 141 of the interposer 103 and each of the semiconductor IC dies 107, and a first molding portion 109 laterally surrounding the plurality of semiconductor IC dies 107. A second side surface 142 of the interposer 103 may be bonded to a plurality of package substrates 111 by a plurality of bonding material portions 117. The package substrates 111 may be laterally confined with respect to the interposer 103 such that at least one horizontal dimension of the interposer 103 may be greater than the corresponding horizontal dimension of the each of the package substrates 111. In some embodiments, one or more of the package substrates 111 may be coreless package substrates 111. At least one functional component 130 may be bonded to the second side surface 142 of the interposer 103. At least a portion of each functional component 130 may be located between the second side surface 142 of the interposer 103 and a first side surface 143 of at least one of the package substrates 111.

A second molding portion 118 may contact the second side surface 142 of the interposer 103 and may laterally surround each of the package substrates 111. The second molding portion 118 may be located within the gap(s) 133 between adjacent package substrates 111 and may also laterally surround the outer periphery of the plurality of package substrates 111. In some embodiments, a thickness, d, of the second molding portion 118 over the side surfaces of the package substrates 111 between the outer periphery of the package substrates 111 and the peripheral side surfaces of the semiconductor package 100 may be least about 40 μm, such as between about 40 μm and about 2000 μm. The side surfaces of the semiconductor package 100 may be formed by the first molding portion 109, the interposer 103, and the second molding portion 118.

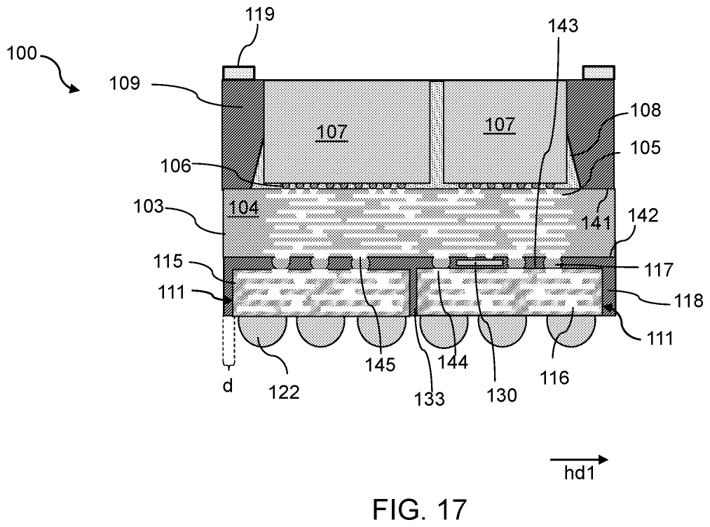

FIG. 17 is a vertical cross-section view of a semiconductor package 100 including a plurality of solder balls 122 located on the lower surface of the package substrate 111 and a ring structure 119 mounted to the upper surface of the first molding portion 109 according to various embodiments of the present disclosure. Referring to FIG. 17, the plurality of solder balls 122 and the ring structure 119 may be as described above with respect to FIG. 10. Thus, repeated discussion of like features is omitted for brevity. In other embodiments, a lid structure 126 and/or an optional thermal interface material (TIM) 125 may be provided as shown in FIG. 12. The semiconductor package 100 may be mounted to a suitable support substrate 123, such as a PCB, as described above with reference to FIG. 11.

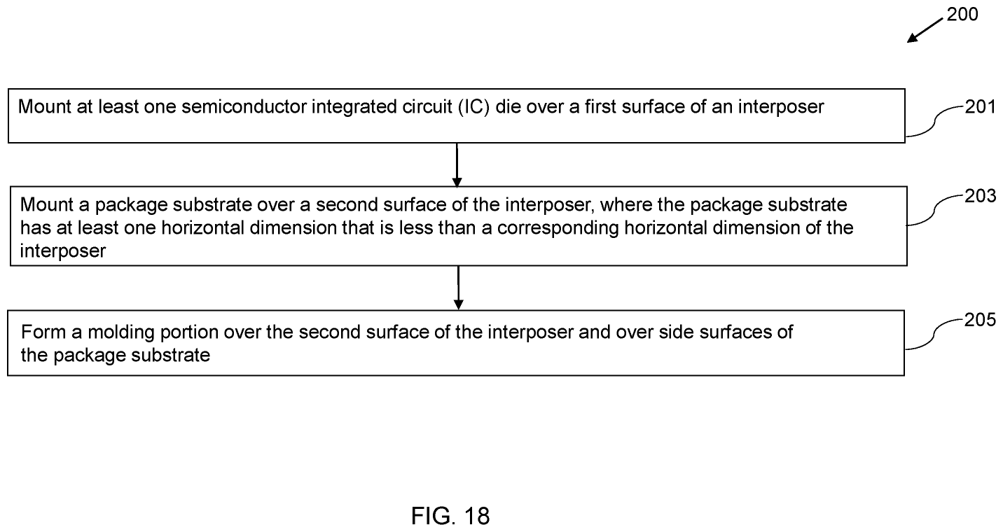

FIG. 18 is a flowchart illustrating a method 200 of fabricating a semiconductor package 100 according to various embodiments of the present disclosure. Referring to FIGS. 2 and 18, in step 201 of embodiment method 200, at least one semiconductor integrated circuit (IC) die 107 may be mounted over a first surface 141 of an interposer 103. Referring to FIGS. 7A, 7B, 14, and 18, in step 203 of embodiment method 200, a package substrate 111 may be mounted over a second surface 142 of the interposer 103, where the package substrate 111 has at least one horizontal dimension that is less than a corresponding horizontal dimension of the interposer 103. Referring to FIGS. 8, 12, 15 and 18, in step 205 of embodiment method 200, a molding portion 118 may be formed over the second surface 142 of the interposer 103 and laterally surrounding the package substrate 111.

Referring to all drawings and according to various embodiments of the present disclosure, a semiconductor package 100 may include an interposer 103, at least one semiconductor integrated circuit (IC) die 107 mounted over a first surface 141 of the interposer 103, a package substrate 111 bonded to a second surface 142 of the interposer 103, and a molding portion 118 contacting the second surface 142 of the interposer 103 and laterally surrounding the package substrate 111.

In an embodiment, the package substrate 111 includes at least one horizontal dimension that is less than the corresponding horizontal dimension of the interposer 103.

In another embodiment, a thickness, d, of the molding portion 118 over a side surface of the package substrate 111 is at least 40 μm.

In another embodiment, a plurality of semiconductor IC dies 107 are mounted over the first surface 141 of the interposer 103 and the molding portion 118 includes a second molding portion 118, and the semiconductor package 100 further includes a first plurality of bonding structures 106 that bond the plurality of semiconductor IC dies 107 to the first surface 141 of the interposer 103, an underfill material portion 108 located between the plurality of semiconductor IC dies 107 and the first surface 141 of the interposer 103 and laterally surrounding the first plurality of bonding structures 106, a first molding portion 109 laterally surrounding the plurality of IC dies 107, and a second plurality of bonding structures 122 that bond the package substrate 111 to the second surface 142 of the interposer, where the second molding portion 118 extends at least partially within a space between the package substrate 111 and the second surface 142 of the interposer 103.

In another embodiment, side surfaces of the semiconductor package 100 are formed by the first molding portion 109, the interposer 103, and the second molding portion 118.

In another embodiment, the semiconductor package 100 further includes at least one of a ring structure 119 and a lid structure 126 mounted to an upper surface of the first molding portion 109.

In another embodiment, a lid structure 126 is mounted to an upper surface of the first molding portion 109 and extends over the plurality of semiconductor IC dies 107, and a thermal interface material (TIM) 125 is located between an upper surface of the plurality of semiconductor IC dies 107 and the lid structure 126.

In another embodiment, the second plurality of bonding structures 122 include solder material portions 122, and the second molding portion 118 contacts and laterally surrounds the solder material portions 122.

In another embodiment, the interposer 103 includes an organic interposer 103 having a thickness of at least 40 μm.

In another embodiment, the package substrate 111 has a thickness of 1.8 mm or less.

In another embodiment, the package substrate 111 a coreless package substrate 111.

In another embodiment, the semiconductor package 100 includes a plurality of package substrates 111 bonded to the second surface 142 of the interposer 103.

In another embodiment, the semiconductor package 100 further includes a functional component 130 bonded to the second surface 142 of the interposer 103, where at least a portion of the functional component 130 is located between the second side surface 142 of the interposer 103 and the package substrate 111.

An additional embodiment is drawn to a semiconductor package 100 including an interposer 103, at least one semiconductor integrated circuit (IC) die 107 mounted over a first surface 141 of the interposer 103, a plurality of package substrates 111 bonded to a second surface 142 of the interposer 103, and a molding portion 118 contacting the second surface 142 of the interposer 103 and located in a gap 133 between adjacent package substrates 111 of the plurality of package substrates 111.

In an embodiment, the molding portion 118 laterally surrounds each of the package substrates 111, and a thickness, d, of the molding portion 118 between an outer periphery of the plurality of package substrates 111 and a periphery of the interposer 103 is at least 40 μm.

In another embodiment, the semiconductor package 100 further includes a functional component 130 mounted to the second surface 142 of the interposer 103, where the molding portion 118 laterally surrounds the functional component 130 and extends within a gap between the functional component 130 and a package substrate 111 of the plurality of package substrates 111.

In another embodiment, the functional component 130 includes at least one of a chiplet, an intelligent power device (IPD), and a bridge die.

An additional embodiment is drawn to a method of fabricating a semiconductor package 100 that includes mounting at least one semiconductor integrated circuit (IC) die 107 over a first surface 141 of an interposer 103, mounting a package substrate 111 over a second surface 142 of the interposer 103, where the package substrate 111 has at least one horizontal dimension that is less than a corresponding horizontal dimension of the interposer 103, and forming a molding portion 118 over the second surface 142 of the interposer 103 and laterally surrounding the package substrate 111.

In an embodiment, the method further includes providing a package structure including the interposer 103 and the at least one semiconductor IC die 107 mounted to the first surface 141 of the interposer 103 on a carrier substrate 110, where the package substrate 111 is mounted to the second surface 142 of the interposer 103 and the molding portion 118 is formed over the second surface 142 of the interposer 103 and laterally surrounding the package substrate 111 while the package structure is located on the carrier substrate 110.

In another embodiment, the method further includes removing the carrier substrate 110, and performing a dicing process through the interposer 103 and the molding portion 118 to provide a discrete semiconductor package 100, where a thickness, d, of the molding portion 118 over a side surface of the package substrate 111 is at least 40 μm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
an interposer;
at least one semiconductor integrated circuit (IC) die mounted over a first surface of the interposer;
a package substrate bonded to a second surface of the interposer; and
a molding portion contacting the second surface of the interposer and laterally surrounding the package substrate.

2. The semiconductor package of claim 1, wherein the package substrate comprises a package substrate interposer width dimension that is less than a corresponding interposer width dimension.

3. The semiconductor package of claim 2, wherein a thickness of the molding portion over a side surface of the package substrate is at least 40 μm.

4. The semiconductor package of claim 1, wherein a plurality of semiconductor IC dies are mounted over the first surface of the interposer and the molding portion comprises a second molding portion, the semiconductor package further comprising:
a first plurality of bonding structures that bond the plurality of semiconductor IC dies to the first surface of the interposer;
an underfill material portion located between the plurality of semiconductor IC dies and the first surface of the interposer and laterally surrounding the first plurality of bonding structures;
a first molding portion laterally surrounding the plurality of IC dies; and
a second plurality of bonding structures that bond the package substrate to the second surface of the interposer, wherein the second molding portion extends at least partially within a space between the package substrate and the second surface of the interposer.

5. The semiconductor package of claim 4, wherein side surfaces of the semiconductor package are formed by the first molding portion, the interposer, and the second molding portion.

6. The semiconductor package of claim 5, further comprising at least one of a ring structure and a lid structure mounted to an upper surface of the first molding portion.

7. The semiconductor package of claim 6, wherein a lid structure is mounted to an upper surface of the first molding portion and extends over the plurality of semiconductor IC dies, and a thermal interface material (TIM) is located between an upper surface of the plurality of semiconductor IC dies and the lid structure.

8. The semiconductor package of claim 4, wherein the second plurality of bonding structures comprises solder material portions, and the second molding portion contacts and laterally surrounds the solder material portions.

9. The semiconductor package of claim 1, wherein the interposer comprises an organic interposer having a thickness of at least 40 μm.

10. The semiconductor package of claim 1, wherein the package substrate has a thickness of 1.8 mm or less.

11. The semiconductor package of claim 10, wherein the package substrate comprises a coreless package substrate.

12. The semiconductor package of claim 1, further comprising a plurality of package substrates bonded to the second surface of the interposer.

13. The semiconductor package of claim 1, further comprising a functional component bonded to the second surface of the interposer, wherein at least a portion of the functional component is located between the second side surface of the interposer and the package substrate.

14. A semiconductor package, comprising:
an interposer;
at least one semiconductor integrated circuit (IC) die mounted over a first surface of the interposer;
a plurality of package substrates bonded to a second surface of the interposer; and
a molding portion contacting the second surface of the interposer and located in a gap between adjacent package substrates of the plurality of package substrates.

15. The semiconductor package of claim 14, wherein the molding portion laterally surrounds each of the package substrates, and a thickness of the molding portion between an outer periphery of the plurality of package substrates and a periphery of the interposer is at least 40 μm.

16. The semiconductor package of claim 14, further comprising a functional component mounted to the second surface of the interposer, wherein the molding portion laterally surrounds the functional component and extends within a gap between the functional component and a package substrate of the plurality of package substrates.

17. The semiconductor package of claim 16, wherein the functional component comprises at least one of a chiplet, an intelligent power device (IPD), and a bridge die.

18. A method of fabricating a semiconductor package, comprising:
mounting at least one semiconductor integrated circuit (IC) die over a first surface of an interposer;
mounting a package substrate over a second surface of the interposer, wherein the package substrate has at least one horizontal dimension that is less than a corresponding horizontal dimension of the interposer; and
forming a molding portion over the second surface of the interposer and laterally surrounding the package substrate.

19. The method of claim 18, further comprising:
providing a package structure comprising the interposer and the at least one semiconductor IC die mounted to the first surface of the interposer on a carrier substrate, wherein the package substrate is mounted to the second surface of the interposer and the molding portion is formed over the second surface of the interposer and laterally surrounding the package substrate while the package structure is located on the carrier substrate.

20. The method of claim 19, further comprising:
removing the carrier substrate; and
performing a dicing process through the interposer and the molding portion to provide a discrete semiconductor package, wherein a thickness of the molding portion over a side surface of the package substrate is at least 40 μm.
